(19) United States
(12) Patent Application Publication
(10) Pub. No.: US 2015/0263272 A1
(43) Pub. Date: Sep. 17, 2015

(54) MANUFACTURING METHOD OF MAGNETIC MEMORY DEVICE AND MANUFACTURING APPARATUS OF MAGNETIC MEMORY DEVICE

(71) Applicant: Kazuhiro TOMIOKA, Seoul (KR)

(72) Inventor: Kazuhiro TOMIOKA, Seoul (KR)

(21) Appl. No.: 14/456,883

(22) Filed: Aug. 11, 2014

Related U.S. Application Data
(60) Provisional application No. 61/952,794, filed on Mar. 13, 2014.

(51) Int. Cl. H01L 43/12; H01J 37/32

(52) U.S. Cl. CPC H01L 43/12; H01J 37/32009; H01J 37/32743

(57) ABSTRACT

According to one embodiment, a method of manufacturing a magnetic memory device, includes accommodating, in an etching chamber, a substrate with a stacked film including a magnetic layer, etching at least a part of the stacked film in the etching chamber to form a columnar structure, and transferring the substrate with the columnar structure from the etching chamber to a transfer chamber in which a reducing purge gas is supplied.

### CROSS-REFERENCE TO RELATED APPLICATIONS

This application claims the benefit of U.S. Provisional Application No. 61/952,794, filed Mar. 13, 2014, the entire contents of which are incorporated herein by reference.

### FIELD

Embodiments described herein relate generally to a method of manufacturing a magnetic memory device, and an apparatus for manufacturing the magnetic memory device.

### BACKGROUND

A magnetic memory device with magnetic elements formed on a semiconductor substrate has been proposed. As the magnetic elements, magnetoresistive effect elements are used, for example.

The magnetic elements are formed by etching a stacked film including magnetic layers to thereby form a columnar structure. However, if the side surface of the columnar structure formed by etching is oxidized, the characteristics and/or reliability of the resultant magnetic memory device may be degraded.

There is a demand for a magnetic memory device manufacturing method capable of preventing oxidation of the side surface of the columnar structure including the magnetic layers.

### BRIEF DESCRIPTION OF THE DRAWINGS

FIG. 1 is a schematic view showing the configuration of an apparatus for manufacturing magnetic memory devices according to embodiments;

FIG. 2 is a schematic cross-sectional view showing a part of a method of manufacturing a magnetic memory device according to a first embodiment;

FIG. 3 is a schematic cross-sectional view showing a part of the method of manufacturing the magnetic memory device according to the first embodiment;

FIG. 4 is a schematic cross-sectional view showing a part of the method of manufacturing the magnetic memory device according to the first embodiment;

FIG. 5 is a schematic cross-sectional view showing a part of a method of manufacturing the magnetic memory device according to a second embodiment;

FIG. 6 is a schematic cross-sectional view showing a part of the method of manufacturing a magnetic memory device according to the second embodiment;

FIG. 7 is a schematic cross-sectional view showing a part of the method of manufacturing a magnetic memory device according to the second embodiment;

FIG. 8 is a schematic cross-sectional view showing a part of the method of manufacturing the magnetic memory device according to the second embodiment;

FIG. 9 is a schematic cross-sectional view showing a part of the method of manufacturing the magnetic memory device according to the second embodiment;

FIG. 10 is a schematic cross-sectional view showing a part of a method of manufacturing the magnetic memory device according to a third embodiment;

FIG. 11 is a schematic cross-sectional view showing a part of the method of manufacturing the magnetic memory device according to the third embodiment;

FIG. 12 is a schematic cross-sectional view showing a part of the method of manufacturing the magnetic memory device according to the third embodiment;

FIG. 13 is a schematic cross-sectional view showing a part of the method of manufacturing a magnetic memory device according to the third embodiment; and

FIG. 14 is a schematic cross-sectional view showing a part of the method of manufacturing the magnetic memory device according to the third embodiment.

### DETAILED DESCRIPTION

In general, according to one embodiment, a method of manufacturing a magnetic memory device, includes: accommodating, in an etching chamber, a substrate with a stacked film including a magnetic layer; etching at least a part of the stacked film in the etching chamber to form a columnar structure; and transferring the substrate with the columnar structure from the etching chamber to a transfer chamber in which a reducing purge gas is supplied.

The embodiments will be described with reference to the accompany drawings.

(Apparatus Configuration)

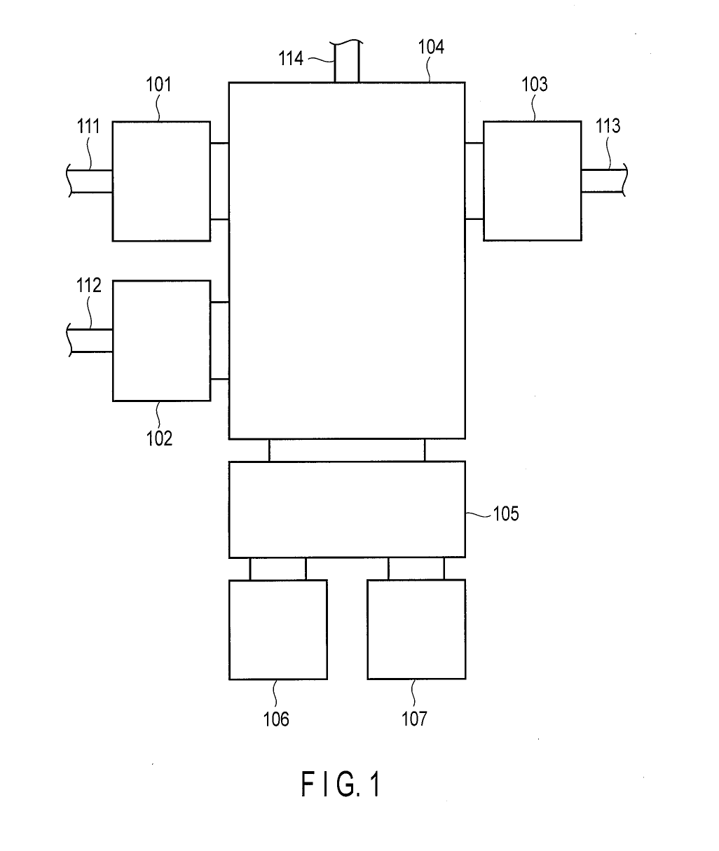

FIG. 1 is a schematic view showing the configuration of an apparatus for manufacturing magnetic memory devices according to embodiments.

The apparatus shown in FIG. 1 comprises an etching chamber 101 for reactive ion etching (RIE), an etching chamber 102 for ion beam etching (IBE), a deposition chamber 103 for deposition, a transfer chamber 104, a load lock 105, a load port 106 and a load port 107. One of the etching chambers 101 and 102 may not be provided.

An etching gas supply section 111, an etching gas supply section 112, a deposition gas supply section 113 and a purge gas supply section 114 are connected to the etching chamber 101, the etching chamber 102, the deposition chamber 103 and the transfer chamber 104, respectively.

### First Embodiment

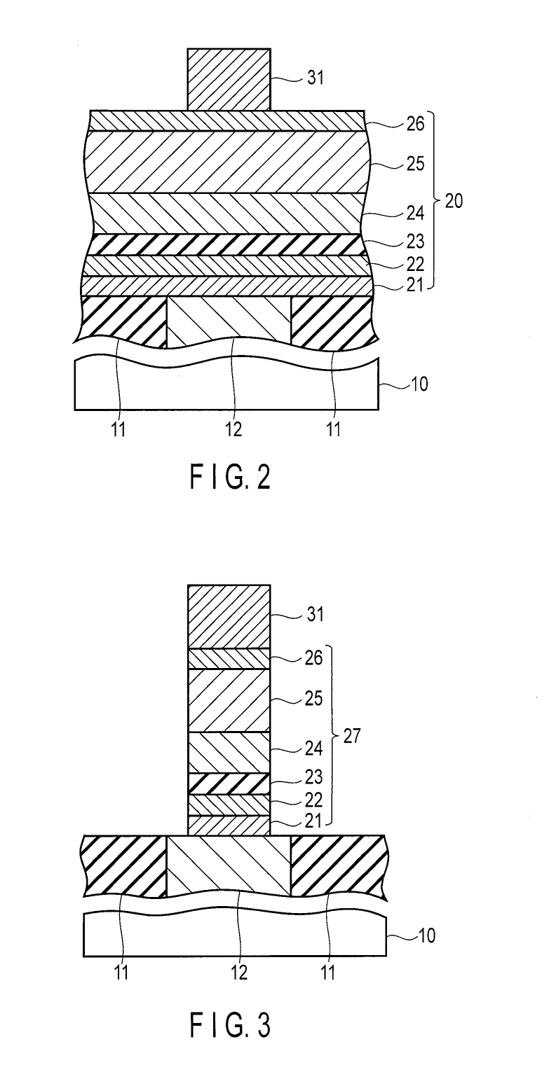

FIGS. 2 to 4 are schematic cross-sectional views showing the method of manufacturing the magnetic memory device of the first embodiment. The manufacturing method of the first embodiment is employed in the apparatus shown in FIG. 1. Further, the manufacturing method of the first embodiment is applied to the manufacture of a magnetic memory device including a magnetoresistive effect element (MTJ element).

Firstly, the process step shown in FIG. 2 is executed. In the step of FIG. 2, an interlayer insulating film 11 and a lower electrode 12 are firstly formed on a substrate 10. The substrate 10 includes a semiconductor substrate, a transistor, wiring, etc. Subsequently, a stacked film 20 including magnetic layers is formed on the interlayer insulating film 11 and the lower electrode 12. The stacked film 20 comprises an under layer 21, a storage layer (first magnetic layer) 22, a tunnel barrier layer (nonmagnetic layer) 23, a reference layer (second magnetic layer) 24, a shift cancelling layer 25 and a cap layer 26.

The under layer 21 is formed of, for example, Hf, AlN or TaAlN. The storage layer 22 is formed of, for example, CoFeB. The tunnel barrier layer 23 is formed of, for example, MgO or AlO. The reference layer 24 is formed of, for example, CoPt, CoMn or (CoPd+CoFeB). The shift cancelling layer 25 is formed of, for example, CoPt, CoMn or CoPd. The cap layer 26 is formed of, for example, Pt, W, Ta or Ru.

After forming the above-mentioned stacked film 20, a hard mask 31 is formed on the cap layer 26. The hard mask is formed of, for example, W, Ta, TaN, Ti, TiN or C (diamond-like carbon or graphite carbon).

Subsequently, the process step shown in FIG. 3 is executed. In the step of FIG. 3, the substrate with the stacked film 20 shown in FIG. 2 is transferred to the etching chamber 101, wherein at least a part of the stacked film 20 is etched to form a columnar structure 27. In the first embodiment, all layers included in the stacked film 20 are etched. More specifically, the cap layer 26, the shift cancelling layer 25, the reference layer 24, the tunnel barrier layer 23, the storage layer 22 and the under layer 21 are etched by RIE, using the hard mask 31 as a mask. The RIE is performed using an etching gas containing a halogen element, such as chlorine. The etching gas is supplied from the etching gas supply section 111 to the etching chamber 101. Further, the etching is performed, with the substrate 10 heated.

After that, the substrate 10 with the columnar structure 27 is transferred from the etching chamber 101 to the transfer chamber 104. In the transfer chamber 104, a reducing purge gas is supplied from the purge gas supply section 114. Namely, the transfer chamber 104 is supplied with the reducing purge gas before receiving the substrate 10. More specifically, the transfer chamber 104 is supplied with the reducing purge gas before a gate valve interposed between the etching chamber 101 and the transfer chamber 104 is opened. The purge gas contains hydrogen gas (H₂ gas). The purge gas may also contain an inert gas, such as Ar. Hydrogen contained in the purge gas may be atomic hydrogen (hydrogen radical) formed by microwave discharge or catalytically formed.

In general, nitrogen gas is often used as the purge gas. However, for some reasons, oxygen also exists in the transfer chamber 104. Therefore, when nitrogen gas is used as the purge gas, the side surface of the columnar structure 27 may be oxidized. Namely, since the columnar structure 27 contains an oxidizable metal, such as iron, the side surface of the columnar structure 27 may be oxidized.

Further, in the etching chamber 101, etching is performed with the temperature of the substrate 10 increased. The temperature of the substrate 10 can be increased by the plasma used for etching. If the temperature is not sufficiently increased by the plasma, the substrate 10 is further heated by a heater. Thus, the temperature of the substrate 10 during etching is higher than in the transfer chamber 104. Namely, the temperature in the etching chamber 101 during etching is higher than in the transfer chamber 104.

Since as described above, etching is performed with the temperature of the substrate 10 increased, the temperature of the substrate 10 is higher than in the transfer chamber 104 when the substrate 10 with the columnar structure 27 is moved from the etching chamber 101 to the transfer chamber 104. Namely, the temperature of the substrate 10 (i.e., the temperature in the etching chamber 101) immediately before the end of etching is higher than in the transfer chamber 104. Even after the substrate 10 is moved into the transfer chamber 104, the temperature of the substrate 10 does not quickly decrease. Thus, the side surface of the columnar structure 27 is liable to be oxidized in the transfer chamber 104.

In the first embodiment, a reducing purge gas is supplied in the transfer chamber 104, and hence the side surface of the columnar structure 27 can be prevented from being oxidized. Namely, since purge is performed using the reducing purge gas, the oxidation of the side surface of the columnar structure 27 can be reliably prevented.

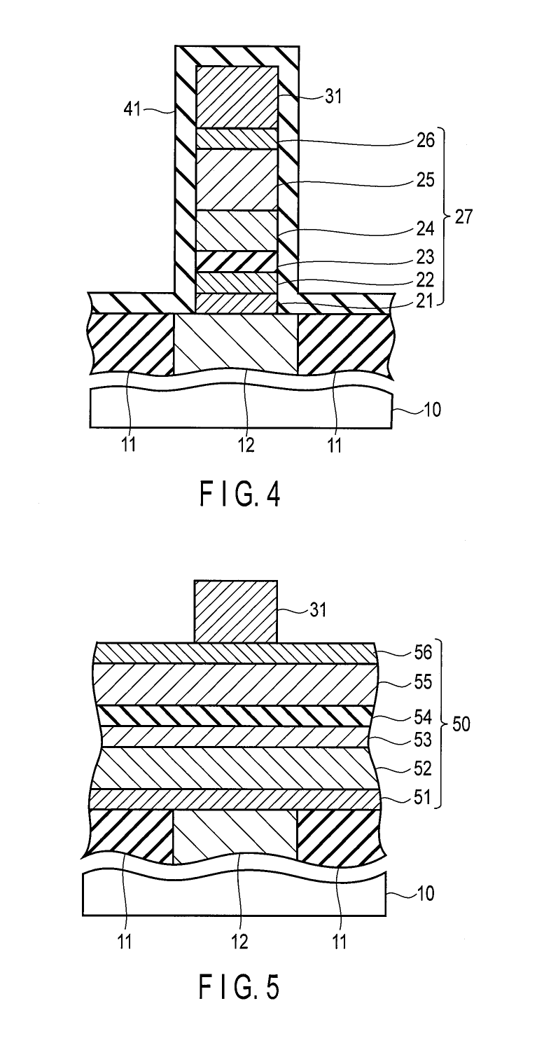

Subsequently, the process step shown in FIG. 4 is executed. In the step of FIG. 4, the substrate 10 with the columnar structure 27 is transferred from the transfer chamber 104 to the deposition chamber 103. In the deposition chamber 103, a protective insulation film 41 is formed to cover the columnar structure 27 and the hard mask 31. A deposition gas is supplied from the deposition gas supply section 113 to the deposition chamber 103. Deposition is performed with the substrate 10 heated. As the protective insulation film 41, a silicon nitride (SiN) film formed by CVD is used.

As described above, a magnetoresistive effect element (MTJ element) covered with the protective insulation film 41 is obtained. The magnetoresistive effect element comprises the storage layer (first magnetic layer) 22, the shift cancelling layer (magnetic layer) 25, the reference layer (second magnetic layer) 24 provided between the storage layer 22 and the shift cancelling layer 25, and the tunnel barrier layer (nonmagnetic layer) 23 provided between the storage layer 22 and the reference layer 24. The storage layer 22 has variable magnetization, and the reference layer 24 and the shift cancelling layer 25 have fixed magnetization.

The other steps including a wiring step, which are not shown, are executed later to produce the magnetic memory device.

As described above, since in the first embodiment, a reducing purge gas is supplied into the transfer chamber 104, oxidation of the side surface of the columnar structure 27 can be prevented, whereby a magnetic memory device excellent in characteristics and reliability can be obtained.

Although the first embodiment employs RIE for the etching step of FIG. 3, IBE may be used for this purpose, instead of RIE. In this case, etching is performed in the etching chamber 102 for IBE. When etching is performed by IBE, an etching gas containing a halogen element or containing no halogen element may be used. For instance, argon (Ar) gas is used as the etching gas.

### Second Embodiment

FIGS. 5 to 9 are schematic cross-sectional views showing a method of manufacturing a magnetic memory device according to a second embodiment. This manufacturing method is also employed in the apparatus shown in FIG. 1. Further, this method is also applied to manufacture of a magnetic memory device including a magnetoresistive effect element. Since the second embodiment is similar to the first embodiment in basic matters, the matters already described in the first embodiment will not be described again.

Firstly, the process step shown in FIG. 5 is executed. In the step of FIG. 5, a stacked film 50 including magnetic layers is formed on the interlayer insulating film 11 and the lower electrode 12 after the interlayer insulating film 11 and the lower electrode 12 are formed. The stacked film 50 comprises an under layer 51, a shift cancelling layer 52, a storage layer (first magnetic layer) 53, a tunnel barrier layer (nonmagnetic layer) 54, a reference layer (second magnetic layer) 55, and a cap layer 56. The materials of these layers are similar to those in the first embodiment.

After forming the above-mentioned stacked film 50, a hard mask 31 is formed on the cap layer 56. The hard mask is formed of the same material as in the first embodiment.

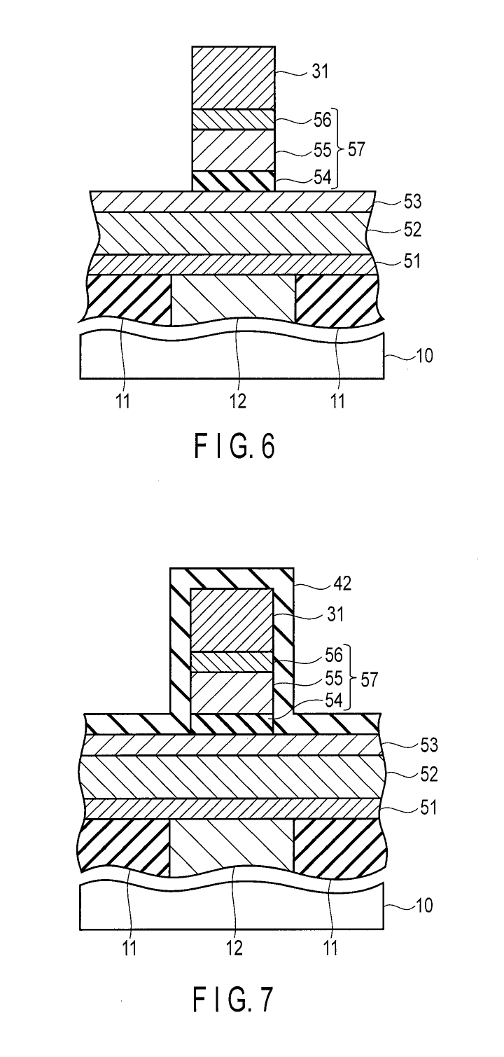

Subsequently, the process step shown in FIG. 6 is executed. In the step of FIG. 6, the substrate 10 with the stacked film 50 is accommodated in the etching chamber 101. In the etching chamber 101, a part of the stacked film 50 is etched to form a columnar structure 57. More specifically, the cap layer 56, the reference layer 55 and the tunnel barrier layer 54 are etched by RIE, using the hard mask 31 as a mask. The etching is performed using an etching gas containing a halogen element, such as chlorine. Further, the etching is performed with the substrate 10 heated.

Thereafter, the substrate 10 with the columnar structure 57 is transferred from the etching chamber 101 to the transfer chamber 104. In the transfer chamber 104, a reducing purge gas is supplied from the purge gas supply section 114. Namely, in the second embodiment, the transfer chamber 104 is supplied with the reducing purge gas before receiving the substrate 10, as in the first embodiment. This purge gas is the same as that of the first embodiment.

In the second embodiment, the reducing purge gas supplied to the transfer chamber 104 prevents oxidation of the side surface of the columnar structure 57, as in the first embodiment.

Thereafter, the process step shown in FIG. 7 is executed. In the step of FIG. 7, the substrate 10 with the columnar structure 57 is transferred from the transfer chamber 104 to the deposition chamber 103. In the deposition chamber 103, a protective insulation film 42 is deposited to cover the columnar structure 57 and the hard mask 31. Deposition is performed with the substrate 10 heated. As the protective insulation film 42, a silicon nitride (SiN) film formed by CVD is used.

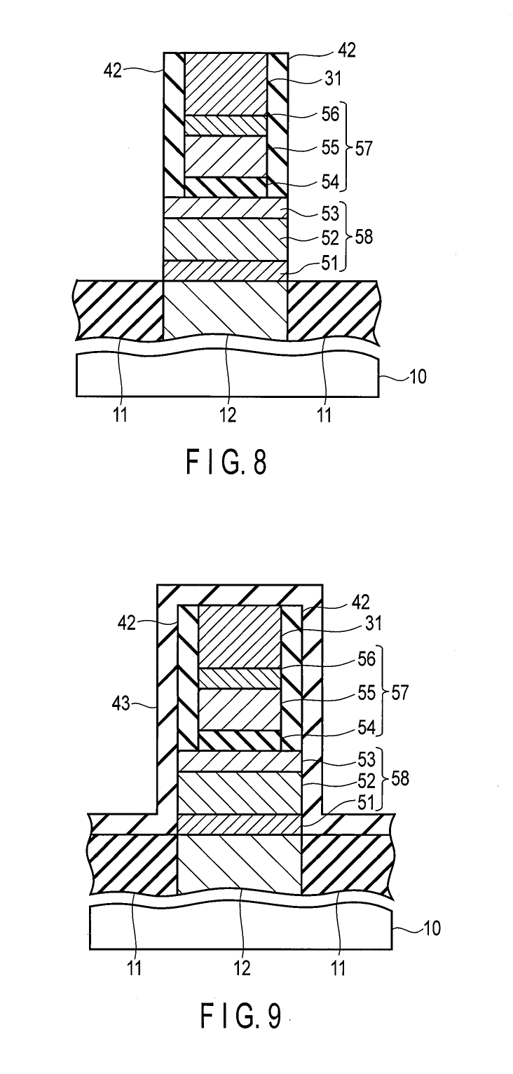

Subsequently, the process step shown in FIG. 8 is executed. In the step of FIG. 8, the substrate 10 with the protective insulation film 42 covering, for example, the columnar structure 57 is transferred from the deposition chamber 103 to the transfer chamber 104. In the transfer chamber 104, a reducing purge gas is supplied from the purge gas supply section 114. Namely, the transfer chamber 104 is supplied with the reducing purge gas before receiving the substrate 10. More specifically, the transfer chamber 104 is supplied with the reducing purge gas before a gate valve interposed between the deposition chamber 103 and the transfer chamber 104 is opened. This purge gas is the same as the above-mentioned purge gas.

After that, the substrate 10 with the protective insulation film 42 is transferred from the transfer chamber 104 to the etching chamber 101. In the etching chamber 101, the protective insulation film 42 and the stacked film (the under layer 51, the shift cancelling layer 52 and the storage layer 53) are etched by RIE, using an etching gas containing a halogen element, such as chlorine. Further, etching is performed with the substrate 10 heated. As a result, a columnar structure 58 including the under layer 51, the shift cancelling layer 52 and the storage layer 53 is formed. The protective insulation film 42 is left on the side surfaces of the columnar structure 57 and the hard mask 31.

Subsequently, the process step shown in FIG. 9 is executed. In the step of FIG. 9, the substrate 10 is transferred from the etching chamber 101 to the transfer chamber 104. In the transfer chamber 104, a reducing purge gas is supplied from the purge gas supply section 114. Namely, the transfer chamber 104 is supplied with the reducing purge gas before receiving the substrate 10, as in the first embodiment. This purge gas is the same as the above-mentioned one.

Also at this time, the reducing purge gas supplied to the transfer chamber 104 prevents oxidation of the side surface of the columnar structure 58.

After that, the substrate 10 provided with, for example, the columnar structure 58 is transferred from the transfer chamber 104 to the deposition chamber 103. In the deposition chamber 103, a protective insulation film 43 is deposited to cover the structure including the columnar structure 57, the columnar structure 58, the hard mask 31 and the protective insulation film 42. Deposition is performed with the substrate 10 heated. As the protective insulation film 43, a silicon nitride (SiN) film formed by CVD is used.

As a result, a magnetoresistive effect element (MTJ element) covered with the protective insulation films 42 and 43 is obtained.

The other steps including a wiring step, which are not shown, are executed later to produce the magnetic memory device.

Since as described above, the reducing purge gas is supplied in the transfer chamber 104, the side surfaces of the columnar structures 57 and 58 can be prevented from oxidation.

Although in the above-described embodiment, the etching process shown in FIG. 6 is realized by RIE, it may be done by IBE. Similarly, the etching process shown in FIG. 8 may also be done by IBE. When etching is performed by IBE, an etching gas containing a halogen element or containing no halogen element may be used. For instance, argon (Ar) gas is used as the etching gas.

### Third Embodiment

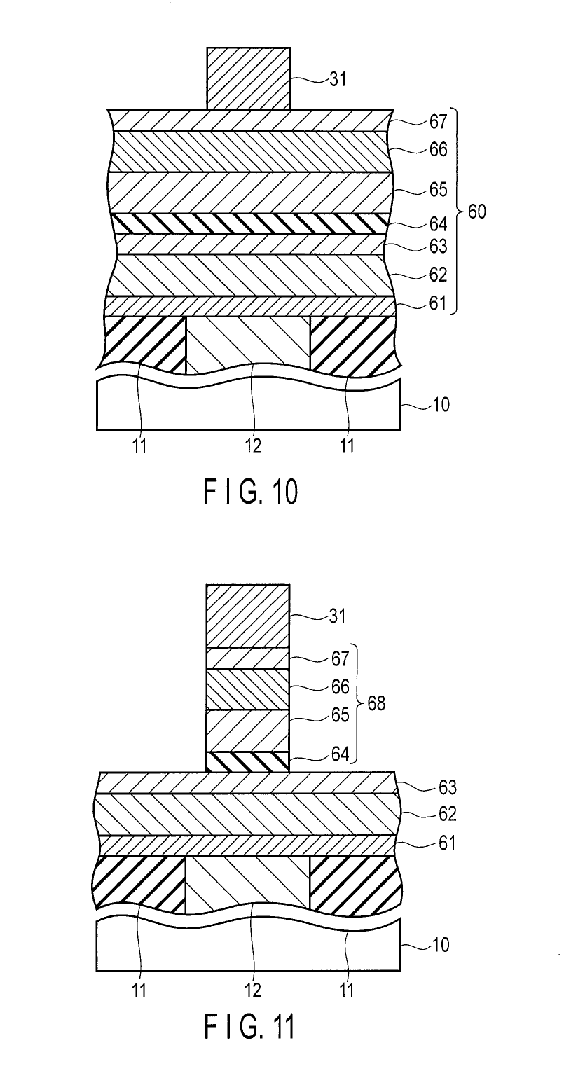

FIGS. 10 to 14 are schematic cross-sectional views showing a method of manufacturing a magnetic memory device according to a third embodiment. This manufacturing method is also employed in the apparatus shown in FIG. 1. Further, this method is also applied to manufacture of a magnetic memory device including a magnetoresistive effect element. Since the third embodiment is similar to the first or second embodiment in basic matters, the matters already described in the first or second embodiment will not be described again.

Firstly, the process step shown in FIG. 10 is executed. In the step of FIG. 10, a stacked film 60 including magnetic layers is formed on the interlayer insulating film 11 and the lower electrode 12 after the interlayer insulating film 11 and the lower electrode 12 are formed on the substrate 10. The stacked film 60 comprises an under layer 61, a shift cancelling layer 62, a storage layer (first magnetic layer) 63, a tunnel barrier layer (nonmagnetic layer) 64, a reference layer (second magnetic layer) 65, a shift cancelling layer 66 and a cap layer 67. The materials of these layers are similar to those in the first embodiment.

After forming the above-mentioned stacked film 60, a hard mask 31 is formed on the cap layer 67. The hard mask 31 is formed of the same material as in the first embodiment.

Subsequently, the process step shown in FIG. 11 is executed. In the step of FIG. 11, the substrate 10 with the stacked film 60 is accommodated in the etching chamber 101, whereby a part of the stacked film 60 is etched to form a columnar structure 68. More specifically, the cap layer 67, the shift cancelling layer 66, the reference layer 65 and the tunnel barrier layer 64 are etched by RIE with the substrate 10 heated, using the hard mask 31 as a mask. The etching is performed using an etching gas containing a halogen element, such as chlorine.

The substrate 10 with the columnar structure 68 is transferred from the etching chamber 101 to the transfer chamber 104. In the transfer chamber 104, a reducing purge gas is supplied from the purge gas supply section 114. Namely, in the third embodiment, the transfer chamber 104 is supplied with the reducing purge gas before receiving the substrate 10, as in the first and second embodiments. This purge gas is the same as the above-mentioned one.

Since thus, the reducing purge gas is supplied in the transfer chamber 104 in the third embodiment, the side surface of the columnar structure 68 can be prevented from oxidation, as in the first embodiment.

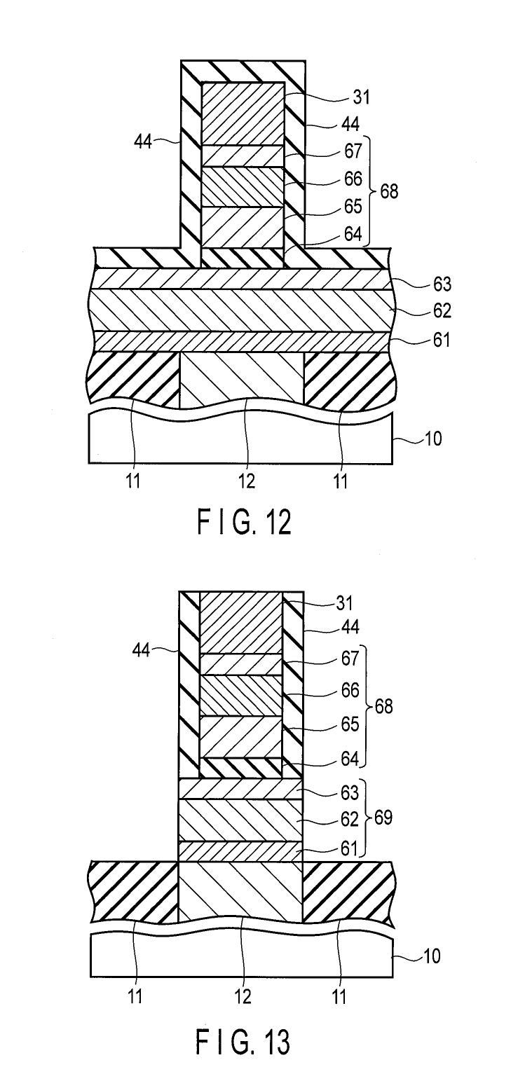

Thereafter, the process step shown in FIG. 12 is executed. In the step of FIG. 12, the substrate 10 with the columnar structure 68 is transferred from the transfer chamber 104 to the deposition chamber 103. In the deposition chamber 103, a protective insulation film 44 is deposited to cover the columnar structure 68 and the hard mask 31. Deposition is performed, with the substrate 10 heated. As the protective insulation film 44, a silicon nitride (SiN) film formed by CVD is used.

After that, the process step shown in FIG. 13 is executed. In the step of FIG. 13, the substrate 10 with the protective insulation film 44 covering, for example, the columnar structure 68 is transferred from the deposition chamber 103 to the transfer chamber 104. In the transfer chamber 104, a reducing purge gas is supplied from the purge gas supply section 114. Namely, the transfer chamber 104 is supplied with the reducing purge gas before receiving the substrate 10, as in the second embodiment. This purge gas is the same as the above-mentioned one.

After that, the substrate 10 with the protective insulation film 44 is transferred from the transfer chamber 104 to the etching chamber 101. In the etching chamber 101, the protective insulation film 44 and the stacked film (the under layer 61, the shift cancelling layer 62 and the storage layer 63) are etched by RIE, using an etching gas containing a halogen element, such as chlorine. Further, etching is performed with the substrate 10 heated. As a result, a columnar structure 69 including the under layer 61, the shift cancelling layer 62 and the storage layer 63 is formed. The protective insulation film 44 is left on the side surface of the columnar structure 68.

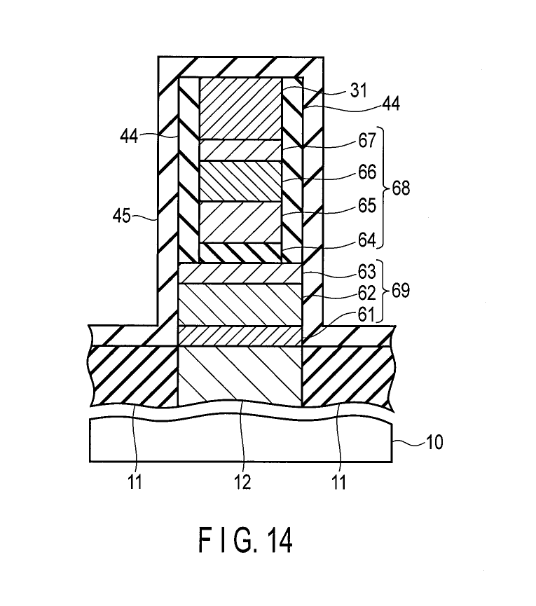

Subsequently, the process step shown in FIG. 14 is executed. In the step of FIG. 14, the substrate 10 is transferred from the etching chamber 101 to the transfer chamber 104. In the transfer chamber 104, a reducing purge gas is supplied from the purge gas supply section 114. Namely, the transfer chamber 104 is supplied with the reducing purge gas before receiving the substrate 10, as in the first and second embodiments. This purge gas is the same as the above-mentioned purge gas.

Also at this time, since the reducing purge gas is supplied in the transfer chamber 104, the side surface of the columnar structure 69 can be prevented from oxidation.

Thereafter, the substrate 10 provided with, for example, the columnar structure 69 is transferred from the transfer chamber 104 to the deposition chamber 103. In the deposition chamber 103, a protective insulation film 45 is deposited to cover the columnar structures 68 and 69, the hard mask 31 and the protective insulation film 44. Deposition is performed, with the substrate 10 heated. As the protective insulation film 45, a silicon nitride (SiN) film formed by CVD is used.

As described above, a magnetoresistive effect element (MTJ element) covered with the protective insulation films 44 and 45 is obtained.

The other steps including a wiring step, which are not shown, are executed later to produce the magnetic memory device.

Since as described above, a reducing purge gas is supplied in the transfer chamber 104 in the third embodiment, the side surfaces of the columnar structures 68 and 69 can be prevented from oxidation.

In addition, although in the third embodiment, the etching process shown in FIG. 11 is realized by RIE, it may be done by IBE. Similarly, the etching process shown in FIG. 13 may also be done by IBE. When etching is performed by IBE, an etching gas containing a halogen element or containing no halogen element may be used. For instance, argon (Ar) gas is used as the etching gas.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a magnetic memory device, comprising:
accommodating, in an etching chamber, a substrate with a stacked film including a magnetic layer;
etching at least a part of the stacked film in the etching chamber to form a columnar structure; and
transferring the substrate with the columnar structure from the etching chamber to a transfer chamber in which a reducing purge gas is supplied.

2. The method of claim 1, wherein the purge gas contains a hydrogen gas.

3. The method of claim 2, wherein the purge gas further contains an inert gas.

4. The method of claim 1, further comprising:
transferring the substrate with the columnar structure from the transfer chamber to a deposition chamber; and
forming, in the deposition chamber, an insulating film covering the columnar structure.

5. The method of claim 4, further comprising transferring the substrate with the protective insulation film from the deposition chamber to the transfer chamber in which the reducing purge gas is supplied.

6. The method of claim 1, wherein when the substrate with the columnar structure is transferred from the etching chamber to the transfer chamber, a temperature of the substrate is higher than a temperature within the transfer chamber.

7. The method of claim 1, wherein etching at least the part of the stacked film is performed using RIE.

8. The method of claim 1, wherein etching at least the part of the stacked film is performed using IBE.

9. The method of claim 1, wherein the stacked film includes a first magnetic layer, a second magnetic layer, and a nonmagnetic layer interposed between the first and second magnetic layers.

10. The method of claim 9, wherein the first magnetic layer is a storage layer, and the second magnetic layer is a reference layer.

11. An apparatus for manufacturing a magnetic memory device, comprising:
an etching chamber accommodating a substrate with a stacked film including a magnetic layer, and etching at least a part of the stacked film to form a columnar structure; and
a transfer chamber in which a reducing purge gas is supplied, and to which the substrate with the columnar structure is transferred from the etching chamber.

12. The apparatus of claim 11, further comprising a purge gas supply section supplying the purge gas into the transfer chamber.

13. The apparatus of claim 11, further comprising a deposition chamber forming a protective insulation film covering the columnar structure.

14. The apparatus of claim 11, wherein the purge gas contains a hydrogen gas.

15. The apparatus of claim 14, wherein the purge gas further contains an inert gas.
